(19) United States
(12) Patent Application Publication
(10) Pub. No.: US 2026/0235961 A1
(43) Pub. Date: Aug. 13, 2026

(54) TUNNEL OPTIC BEAM HOMOGENIZER FOR EUV ILLUMINATION SYSTEMS

(71) Applicant: KLA Corporation, Milpitas, CA (US)

(72) Inventors: Frank Chilese, Milpitas, CA (US); Yue Wang, Milpitas, CA (US); Hongqi Li, Milpitas, CA (US); Matthew Van Doren, Milpitas, CA (US); Amanjot Gill, Milpitas, CA (US); Shuqi Zheng, Milpitas, CA (US); Junwon Lee, Milpitas, CA (US)

(21) Appl. No.: 19/048,451

(22) Filed: Feb. 7, 2025

(51) Int. Cl. G03F 7/00

(52) U.S. Cl. CPC G03F 7/70166; G03F 7/70141; G03F 7/702; G03F 7/70833

(57) ABSTRACT

A tunnel optic has an aperture extending from a beam entrance to a beam exit. The tunnel optic includes four rectangular members secured together by a plurality of fasteners, and each rectangular member has a first side, a second side adjacent to the first side, a third side opposite to the first side, and a fourth side opposite to the second side. Each rectangular member has a plurality of first mounting holes extending from the first side to the third side and a plurality of second mounting holes extending from the second side to the third side. The plurality of fasteners extend through the plurality of first mounting holes and the plurality of second mounting holes of each rectangular member to secure the four rectangular members together. The aperture is defined by a portion of the third side of each of the four rectangular members.

### FIELD OF THE DISCLOSURE

This disclosure relates to beam homogenizing optics and, more particularly, to a tunnel optic for homogenizing a beam of extreme ultra-violet (EUV) light.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a semiconductor workpiece (e.g., wafer, substrate, display panel, etc.) using a large number of fabrication processes to form various features and multiple levels of the semiconductor devices. For example, lithography is a semiconductor fabrication process that involves transferring a pattern from a reticle to a photoresist arranged on a semiconductor workpiece (e.g., a silicon wafer). Additional examples of semiconductor fabrication processes include, but are not limited to, chemical-mechanical polishing (CMP), etch, deposition, and ion implantation. Multiple semiconductor devices may be fabricated in an arrangement on a single semiconductor workpiece that are separated into individual semiconductor devices.

In a lithography process, an illumination system directs light (such as, for example, Deep Ultraviolet (DUV) light, Extreme Ultraviolet (EUV) light, or the like) onto a reticle, which reflects the light in a pattern onto a semiconductor workpiece to expose photoresist to the light according to the pattern of the reticle. A typical beam profile of DUV or EUV light produced by a light source has a Gaussian profile, where the intensity of the light is significantly higher at the center of the beam than at its edge, which may reduce the ability of the illumination system to transfer the reticle pattern to the workpiece. Beam homogenizers can be used to improve the uniformity of the beam profile.

Typical homogenizers include hollow waveguides, in which light entering the hollow structure experiences multiple grazing-incidence reflections to produce a flat beam profile at the exit. These homogenizers are often constructed of fused silica or glass that are optically contacted and sealed with adhesives. However, this construction can be less robust and easily broken. If the alignment of the hollow surfaces does not meet specification (e.g., the surfaces are not uniformly straight or perpendicular), the components of the homogenizer cannot be removed or readjusted.

Therefore, what is needed is an improved beam homogenizer for EUV lithography.

### BRIEF SUMMARY OF THE DISCLOSURE

An embodiment of the present disclosure provides a system comprising a tunnel optic having a beam entrance, a beam exit opposite from the beam entrance, and an aperture extending from the beam entrance to the beam exit. The tunnel optic may comprise four rectangular members secured together by a plurality of fasteners, and each rectangular member may have a first side, a second side adjacent to the first side, a third side opposite to the first side, and a fourth side opposite to the second side. A plurality of first mounting holes may be defined in each rectangular member extending from the first side to the third side, and a plurality of second mounting holes may be defined in each rectangular member extending from the second side to the third side. The plurality of first mounting holes may be parallel to the plurality of second mounting holes in each rectangular member, and the plurality of first mounting holes of one rectangular member may be aligned with the plurality of second mounting holes of an adjacent rectangular member, such that the plurality of fasteners extend through the plurality of first mounting holes and the plurality of second mounting holes of each rectangular member to secure the four rectangular members together. The aperture of the tunnel optic may be defined by a portion of the third side of each of the four rectangular members.

In some embodiments, the four rectangular members may be comprised of nickel-plated aluminum.

In some embodiments, a reflective coating may be provided on the third side of each of the four rectangular members defining the aperture.

In some embodiments, the reflective coating may be an extreme ultra-violet (EUV) light reflective coating. The tunnel optic may be configured to homogenize EUV light traveling from the beam entrance to the beam exit.

In some embodiments, the plurality of first mounting holes may each have a counter bore on the first side defining a first bearing surface. The plurality of second mounting holes may each have a counter bore hole on the second side defining a second bearing surface.

In some embodiments, the plurality of fasteners may each comprise a bolt threadably connected to a nut. A bolt head of the bolt may be engaged against the first bearing surface, and the nut may be engaged against the second bearing surface.

In some embodiments, the plurality of fasteners may each further comprise a first spring washer provided between the bolt head and the first bearing surface and a second spring washer provided between the nut and the second bearing surface.

In some embodiments, the plurality of first mounting holes may be arranged colinearly on the first side, and the plurality of second mounting holes may be arranged colinearly on the second side.

In some embodiments, the plurality of first mounting holes may comprise a first entrance mounting hole arranged proximal to the beam entrance, a first exit mounting hole arranged proximal to the beam exit, and a plurality of first intermediate mounting holes arranged between the first entrance mounting hole and the first exit mounting hole. A spacing between the first entrance mounting hole and a nearest one of the plurality of first intermediate mounting holes may be less than a spacing between the plurality of first intermediate mounting holes. A spacing between the first exit mounting hole and a nearest one of the plurality of first intermediate mounting holes may be less than the spacing between the plurality of first intermediate mounting holes.

In some embodiments, the plurality of fasteners may be secured within the plurality of first intermediate mounting holes prior to the first entrance mounting hole and the first exit mounting hole.

In some embodiments, a distance between the first side and the third side may be less than a distance between the second side and the fourth side, which may define the portion of the third side of each of the four rectangular members that forms the aperture of the tunnel optic.

In some embodiments, the four rectangular members may be arranged rotationally symmetrical relative to the aperture.

In some embodiments, the system may further comprise a light source configured to emit EUV light, a steering mirror configured to direct the EUV light to the beam entrance of the tunnel optic, and a reticle stage configured to support a reticle pattern illuminated by the EUV light from the beam exit of the tunnel optic.

In some embodiments, the system may further comprise an entrance sensor arranged proximal to the beam entrance. The entrance sensor may be configured to detect an alignment of the EUV light relative to the aperture of the tunnel optic.

In some embodiments, the system may further comprise an exit sensor arranged proximal to the beam exit. The exit sensor may be configured to detect an intensity of the EUV light exiting the tunnel optic.

In some embodiments, the system may further comprise a carrier configured to support the entrance sensor, the tunnel optic, and the exit sensor, and an optical stage configured to move the carrier relative to the EUV light to align the EUV light with the aperture of the tunnel optic based on feedback from the entrance sensor.

In some embodiments, the light source may be configured to emit pulses of EUV light, and the exit sensor may be configured to detect the intensity of each pulse of EUV light exiting the tunnel optic.

Another embodiment of the present disclosure provides a method. The method may comprise providing four rectangular members each having a first side, a second side adjacent to the first side, a third side opposite to the first side, and a fourth side opposite to the second side. The method may further comprise securing the four rectangular members together with a plurality of fasteners to form a tunnel optic having a beam entrance, a beam exit opposite from the beam entrance, and an aperture extending from the beam entrance to the beam exit. A plurality of first mounting holes may be defined in each rectangular member extending from the first side to the third side, and a plurality of second mounting holes may be defined in each rectangular member extending from the second side to the third side. The plurality of first mounting holes may be parallel to the plurality of second mounting holes in each rectangular member, and the plurality of first mounting holes of one rectangular member may be aligned with the plurality of second mounting holes of an adjacent rectangular member, such that the plurality of fasteners extend through the plurality of first mounting holes and the plurality of second mounting holes of each rectangular member to secure the four rectangular members together. The aperture of the tunnel optic may be defined by a portion of the third side of each of the four rectangular members.

In some embodiments, the plurality of first mounting holes may comprise a first entrance mounting hole arranged proximal to the beam entrance, a first exit mounting hole arranged proximal to the beam exit, and a plurality of first intermediate mounting holes arranged between the first entrance mounting hole and the first exit mounting hole. Securing the four rectangular members together with the plurality of fasteners may comprise: securing the plurality of fasteners in the plurality of first intermediate mounting holes; and securing the plurality of fasteners in the first entrance mounting hole and the first exit mounting hole.

In some embodiments, before securing the four rectangular members together with the plurality of fasteners, the method may further comprise arranging the four rectangular members rotationally symmetrical relative to the aperture, such that the plurality of first mounting holes of one rectangular member are aligned with the plurality of second mounting holes of an adjacent rectangular member.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of a system according to an embodiment of the present disclosure;

FIG. 2 is a side view of a tunnel optic of a system according to an embodiment of the present disclosure;

FIG. 3 is a top view of the tunnel optic of FIG. 2;

FIG. 4 is a section view along line A-A of the tunnel optic of FIG. 2;

FIG. 5 is a second view along line B-B of the tunnel optic of FIG. 2;

FIG. 6 is a flowchart of a method according to an embodiment of the present disclosure; and

FIG. 7 is a flowchart of a method according to another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

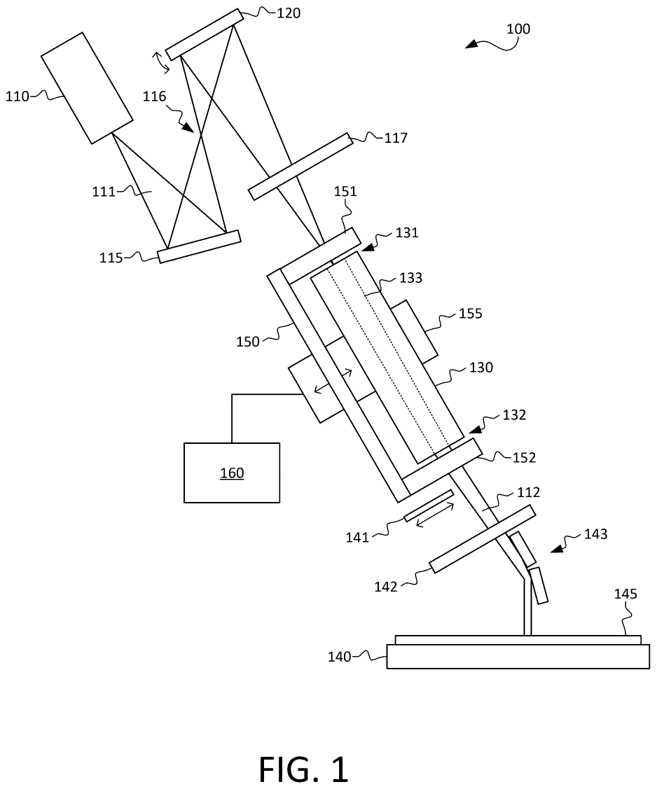

An embodiment of the present disclosure provides a system 100. As shown in FIG. 1, the system 100 may comprise a light source 110. The light source 110 may be configured to emit extreme ultra-violet (EUV) light 111. For example, the light source 110 may be a laser produced plasma (LPP) light source (e.g., an Xe or Sn driven LPP light source, which may use a high intensity infrared laser focused on a solid source to create EUV light) or a discharge produced plasma (DPP) light source (e.g., an Xe driven DPP, which may create an electrical discharge through a gaseous cloud to produce EUV light) configured to emit EUV light 111. In some embodiments, the light source 110 may be configured to emit pulses of EUV light 111. Alternatively, the light source 110 may be configured to emit a continuous beam of EUV light 111.

The system 100 may further comprise one or more optical elements configured to direct the EUV light 111 to navigate through the system 100. For example, the system 100 may further comprise a steering mirror 120. The steering mirror 120 may be configured to adjust the angle of incidence of the EUV light 111 to direct the EUV light 111 to other elements of the system 100. The steering mirror 120 may comprise a fast scanning mirror (FSM), a galvanometer mirror, a liquid-crystal spatial light modulator (LC-SLM), an acousto-optic deflector (AOD), a micro-electro-mechanical system (MEMS) mirror, electro-optic beam deflector, or other type of optical element configured to dynamically control the angle of the EUV light 111. The system 100 may further comprise a collector mirror 115 configured to direct the EUV light 111 from the light source 110 to the steering mirror 120. In some embodiments, the collector mirror 115 and the steering mirror 120 may be elliptical mirrors that refocus light from one spot to another spot. For example, the collector mirror 115 may be configured to refocus the EUV light 111 from the small plasma spot of the light source 110 to an intermediate focus 116 between the collector mirror 115 and the steering mirror 120, and the steering mirror 120 may be configured to refocus the EUV light from the intermediate focus 116 to a beam entrance 131 of a tunnel optic 130, as further described below.

The system 100 may further comprise a tunnel optic 130. The tunnel optic 130 may have a beam entrance 131, a beam exit 132 opposite from the beam entrance 131, and an aperture 133 extending from the beam entrance 131 to the beam exit 132. The steering mirror 120 may be configured to direct the EUV light 111 to the beam entrance 131 of the tunnel optic 130. The tunnel optic 130 may be configured to homogenize the EUV light 111 traveling through the aperture 133 from the beam entrance 131 to the beam exit 132. In other words, the EUV light 111 entering the tunnel optic 130 may have a non-uniform beam profile (e.g., a Gaussian profile), and after traveling through the aperture 133 of the tunnel optic 130, uniform EUV light 112 may exit the tunnel optic 130 from the beam exit 132 having a flat, uniform beam profile.

The system 100 may further comprise a reticle stage 140. The reticle stage 140 may be configured to support a reticle pattern 145. The reticle stage 140 may position the reticle pattern 145 in the path of the uniform EUV light 112 from the beam exit 132 of the tunnel optic 130 to be illuminated by the uniform EUV light 112, after it has gone through an illumination aperture and then a focusing element. The uniform EUV light 112 reflected by the reticle pattern 145, which may be used as a photomask for EUV lithography of a workpiece (e.g., a semiconductor wafer, substrate, chip, printed circuit board (PCB), integrated circuit (IC), flat panel display (FPD), or other devices).

The system 100 may further comprise an entrance sensor 151. The entrance sensor 151 may be arranged proximal to the beam entrance 131 of the tunnel optic 130. The entrance sensor 151 may be configured to detect an alignment of the EUV light 111 relative to the aperture 133 of the tunnel optic 130. For example, the entrance sensor 151 may be a quad-cell or octo-cell sensor configured to detect the alignment of the EUV light 111 relative to the aperture 133 of the tunnel optic 130 based on an amount of the beam of EUV light 111 clipped onto each cell of the entrance sensor 151. The entrance sensor 151 may be, for example, the position sensor described in U.S. patent application Ser. No. 18/941,459, the entire disclosure of which is hereby incorporated by reference herein.

The system 100 may further comprise an exit sensor 153. The exit sensor 152 may be arranged proximal to the beam exit 132 of the tunnel optic 130. The exit sensor 152 may be configured to detect an intensity of the uniform EUV light 112 (or each pulse of uniform EUV light 112) exiting the tunnel optic 130. In some embodiments, the exit sensor 152 may be configured to pick off portions of the uniform EUV light 112 (e.g., upper right and left corners) which are not used for inspection by downstream detectors (e.g., three independent time delay and integration (TDI) sensors may detect the lower right and lower right corners and the upper middle of the light). Accordingly, the exit sensor 152 may not interfere with downstream detection.

The system 100 may further comprise a carrier 150 configured to support the tunnel optic 130. In some embodiments, the carrier 150 may be further configured to support the entrance sensor 151 and/or the exit sensor 152. The system 100 may further comprise an optical stage 155 configured to move the carrier 150 relative to the EUV light 111 to align the EUV light 111 with the aperture 133 of the tunnel optic 130 at the beam entrance 131. The optical stage 155 may be configured to move the carrier 150 in one or more planar directions (i.e., X and Y directions) and/or rotate the carrier 150 (e.g., X-axis rotation or Y-axis rotation). In some embodiments, the optical stage may be configured to move the carrier 150 relative to the EUV light 111 to align the EUV light 111 with the aperture 133 of the tunnel optic 130 based on feedback from the entrance sensor 151.

The system 100 may further comprise additional optical elements disposed on the path of the EUV light 111 or the uniform EUV light 112. For example, the system 100 may further comprise a spectral purity filter 117 disposed in the path of the EUV light 111 between the steering mirror 120 and the tunnel optic 130. The spectral purity filter 117 may be a bandpass filter that passes only a portion of the EUV light 111. The system 100 may further comprise a shutter 141 disposed in the path of the uniform EUV light 112 between the tunnel optic 130 and the reticle stage 140. The shutter 141 may be configured to selectively block or reflect the uniform EUV light 112 from reaching the reticle stage 140. The system 100 may further comprise an illumination aperture assembly 142 disposed in the path of the uniform EUV light 112 between the tunnel optic 130 and the reticle stage 140. The illumination aperture assembly 142 may be configured to block parts of the uniform EUV light 112 in order to better image certain kinds of defects on the reticle pattern 145. The system 100 may further comprise a Wolter Relay 143 disposed in the path of the uniform EUV light 112 between the tunnel optic 130 and the reticle stage 140. The Wolter Relay 143 may comprise a pair of mirrors configured to reflect the uniform EUV light 112 with grazing incidence to focus the uniform EUV light 112 onto the reticle pattern 145. The system 100 may further comprise additional optical elements and is not limited by the exemplary elements provided herein.

The system 100 may further comprise a processor 160. The processor 160 may include a microprocessor, a microcontroller, or other devices. The processor 160 may be coupled to the components of the system 100 in any suitable manner (e.g., via one or more transmission media, which may include wired and/or wireless transmission media) such that the processor 160 can receive output. The processor 160 may be configured to perform a number of functions using the output. An inspection tool can receive instructions or other information from the processor 160. The processor 160 optionally may be in electronic communication with another inspection tool, a metrology tool, a repair tool, or a review tool (not illustrated) to receive additional information or send instructions.

The processor 160 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 160 may be disposed in or otherwise part of the system 100 or another device. In an example, the processor 160 may be part of a standalone control unit or in a centralized quality control unit. Multiple processors 160 may be used, defining multiple subsystems of the system 100.

The processor 160 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 160 to implement various methods and functions may be stored in readable storage media, such as a memory.

If the system 100 includes more than one subsystem, then the different processors 160 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 160 may be configured to perform a number of functions using the output of the system 100 or other output. For instance, the processor 160 may be configured to send the output to an electronic data storage unit or another storage medium. The processor 160 may be further configured as described herein.

The processor 160 may be configured according to any of the embodiments described herein. The processor 160 also may be configured to perform other functions or additional steps using the output of the system 100 or using images or data from other sources.

The processor 160 may be communicatively coupled to any of the various components or sub-systems of system 100 in any manner known in the art. Moreover, the processor 160 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 160 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 160 (or computer subsystem) or, alternatively, multiple processors 160 (or multiple computer subsystems). Moreover, different sub-systems of the system 100 may include one or more computing or logic systems. Therefore, the above description should not be interpreted as a limitation on the present disclosure but merely an illustration.

The processor 160 may be in electronic communication with the light source 110. For example, the processor 160 may be configured to send instructions to the light source 110 to emit the EUV light 111. The instructions may include, for example, a frequency of pulses of the EUV light 111.

The processor 160 may be in electronic communication with the steering mirror 120. For example, the processor 160 may be configured to send instructions to one or more actuators to move the steering mirror 120 to adjust the angle of the EUV light 111 incident on the tunnel optic 130, so the EUV light 111 is aligned with the aperture 133 of the tunnel optic 130 at the beam entrance 131.

The processor 160 may be in electronic communication with the optical stage 155. For example, the processor 160 may be configured to send instructions to one or more actuators to move the optical stage 155 to adjust the alignment of the tunnel optic 130 relative to the EUV light 111 from the steering mirror 120, so that the EUV light 111 is aligned with the aperture 133 of the tunnel optic 130 at the beam entrance 131.

The processor 160 may be in electronic communication with the entrance sensor 151. For example, the processor 160 may be configured to receive feedback signals from the entrance sensor 151, which may indicate the alignment of the tunnel optic 130 relative to the EUV light 111. The processor 160 may use the feedback signals from the entrance sensor 151 to instruct movements of the steering mirror 120 or the optical stage 155 to align the EUV light 111 with the aperture 133 of the tunnel optic 130 at the beam entrance 131.

The processor 160 may be in electronic communication with the exit sensor 152. For example, the processor 160 may be configured to receive feedback signals from the exit sensor 152, which may indicate the intensity of the uniform EUV light 112 exiting the tunnel optic 130 from the beam exit 132. The processor 160 may use the feedback signals from the exit sensor 152 to account for the uniform EUV light 112 reflected by the reticle pattern 145 in each lithographic process.

The processor 160 may be in electronic communication with the reticle stage 140. For example, the processor 160 may be configured to send instructions to one or more actuators to move the reticle stage 140 to adjust the location where the uniform EUV light 112 is incident on the reticle pattern 145 which defines which portion of the reticle pattern 145 is transferred to a workpiece as a photomask.

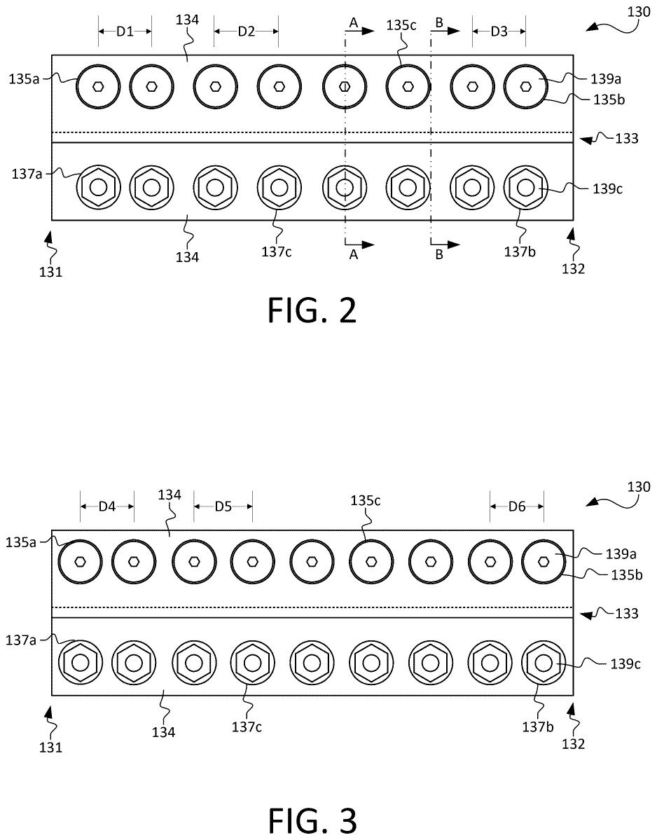

Referring to FIGS. 2-5, the tunnel optic 130 may comprise four rectangular members 134. Each rectangular member 134 may have a first side 134a, a second side 134b adjacent to the first side 134a, a third side 134c opposite to the first side 134a, and a fourth side 134d opposite to the second side 134b. As described herein, the first side 134a, the second side 134b, the third side 134c, and the fourth side 134d may refer to the four perpendicular sides of each rectangular member 134, while the edges connecting these sides may be rounded, chamfered, or have no transitional surface(s). The four rectangular members 134 may be secured together by a plurality of fasteners 139 or by optical contacting or adhesive bonding. In the case of fasteners, the four rectangular members 134 may be made from ductile materials (e.g., metals), such as, for example, aluminum, aluminum alloys (e.g., nickel-plated aluminum), stainless steel alloys, titanium, titanium alloys, nickel-iron alloys (e.g., Invar 36), or other materials that may be highly reflective when polished or coated with a reflective coating. In the case of optical contacting or adhesive bonding, the four rectangular members 134 may be made from glass or ceramic materials.

A plurality of first mounting holes 135 may be defined in each rectangular member 134 extending from the first side 134a to the third side 134c. A plurality of second mounting holes 137 may be defined in each rectangular member 134 extending from the second side 134b to the fourth side 134d. The plurality of first mounting holes 135 may be parallel to the plurality of second mounting holes 137 in each rectangular member 134. In other words, the plurality of first mounting holes 135 and the plurality of second mounting holes 137 may not intersect within each rectangular member 134.

The plurality of first mounting holes 135 of one rectangular member 134 may be aligned with the plurality of second mounting holes 137 of an adjacent rectangular member 134, such that the plurality of fasteners 139 extend through the plurality of first mounting holes 135 and the plurality of second mounting holes 137 of each rectangular member 134 to secure the four rectangular members 134 together. The aperture 133 of the tunnel optic 130 may be defined by a portion of the third side 134c of each of the four rectangular members 134. In some embodiments, the four rectangular members 134 may be arranged rotationally symmetrical relative to the aperture 133. In other words, the third side 134c of each rectangular member 134 may abut with the fourth side 134d of an adjacent rectangular member 134, such that the plurality of first mounting holes 135 are aligned with the plurality of second mounting holes 137 of the adjacent rectangular members 134 surrounding the aperture 133.

In some embodiments, a reflective coating may be provided on the third side 134c of each of the four rectangular members 134 defining the aperture 133 of the tunnel optic 130. For example, the reflective coating may be an EUV light reflective coating, such that the tunnel optic 130 is configured to homogenize the EUV light 111 traveling from the beam entrance 131 to the beam exit 132 through the aperture 133. The composition of the reflective coating may depend on the angle of incidence of the EUV light 111 entering the beam entrance 131. For example, for an angle of incidence of 15 degrees or less (i.e., grazing incidence), the reflective coating may be comprised of Mb, Ru, Nb, Zr, Rh, Pd, Au, Pt, or any combination thereof. The reflective coating may be provided on the entire surface of the third side 134c of each rectangular member 134, which may provide a consistent thickness for contact between the third side 134c of each rectangular member 134 with the fourth side 134d of an adjacent rectangular member 134. Alternatively, the reflective coating may be provided at least on the portion of the third side 134c of each of the four rectangular members 134 that define the aperture 133 of the tunnel optic 130.

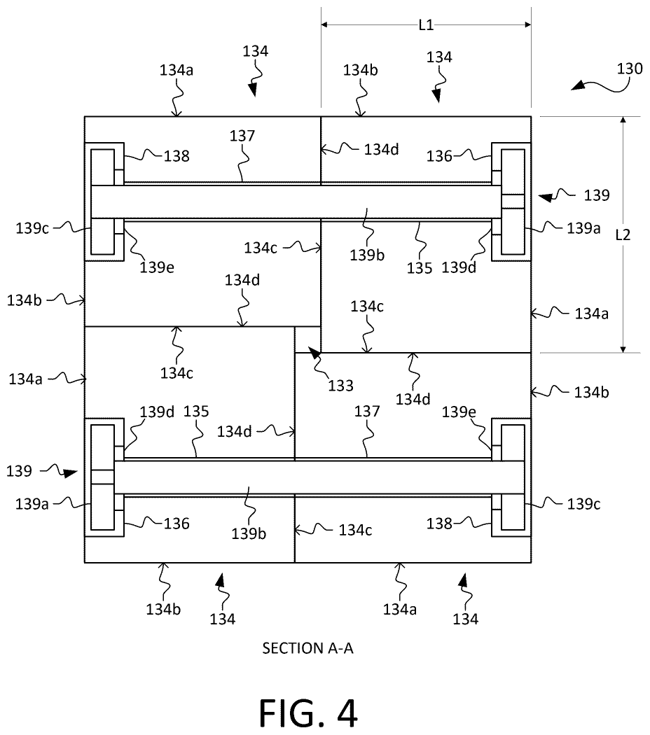

Referring to FIG. 4, a distance L1 between the first side 134a and the third side 134c may be less than a distance L2 between the second side 134b and the fourth side 134d. The difference between the distance L1 and the distance L2 may define the portion of the third side 134c of each of the four rectangular members 134 that forms the aperture 133 of the tunnel optic 130. In an instance, the width of each side of the aperture 133 may be about 1 mm. With the distance L1 and the distance L2 being similar in size, each rectangular member 134 may have a substantially square cross-section, which may improve the stiffness of the tunnel optic 130 when the four rectangular members 134 are secured together. The tunnel optic 130 may be 50 to 300 times longer than the width of the aperture 133, which may ensure that all photons bounce multiple times before reaching the beam exit 132 to homogenize the EUV light 111 into the uniform EUV light 112. In an instance, the tunnel optic 130 may be about 200 times longer than the width of the aperture 133.

In some embodiments, the plurality of first mounting holes 135 may each have a counter bore on the first side 134a defining a first bearing surface 136. Similarly, the plurality of second mounting holes 137 may each have a counter bore hole on the second side 134b defining a second bearing surface 138. The plurality of fasteners 139 may be engaged against the first bearing surface 136 and the second bearing surface 138 to secure the four rectangular members 134 together.

In some embodiments, the plurality of fasteners 139 may each comprise a bolt including a bolt head 139a and a shaft 139b that is threadably connected to a nut 139c. The bolt head 139a may engage against the first bearing surface 136, and the nut may engage against the second bearing surface 138 to secure the four rectangular members 134 together.

In some embodiments, the plurality of fasteners 139 may each further comprise a first spring washer 139d and a second spring washer 139e. The first spring washer 139d and the second spring washer 139e may be clover springs, Belleville springs, wave springs, or other types of spring washers. The first spring washer 139d may be provided between the bolt head 139a and the first bearing surface 136, and the second spring washer 139e may be provided between the nut 139c and the second bearing surface 138. The first spring washer 139d and the second spring washer 139e may allow the force applied to the rectangular members 134 to be controlled and finely tuned based on known spring constants.

In some embodiments, the plurality of first mounting holes 135 may be arranged colinearly on the first side 134a of each rectangular member 134. The plurality of second mounting holes 137 may be arranged colinearly on the second side 134b of each rectangular member 134. As shown in FIG. 2 and FIG. 3, the plurality of first mounting holes 135 and the plurality of second mounting holes 137 on adjacent rectangular members 134 may be in line with each other, while also being parallel to the plurality of first mounting holes 135 and the plurality of second mounting holes 137 of a given rectangular member 134. Accordingly, the four rectangular members 134 may have different numbers of first mounting holes 135 and second mounting holes 137 (e.g., eight in FIG. 2 and nine in FIG. 3) to maintain alignment and parallelism between adjacent rectangular members 134.

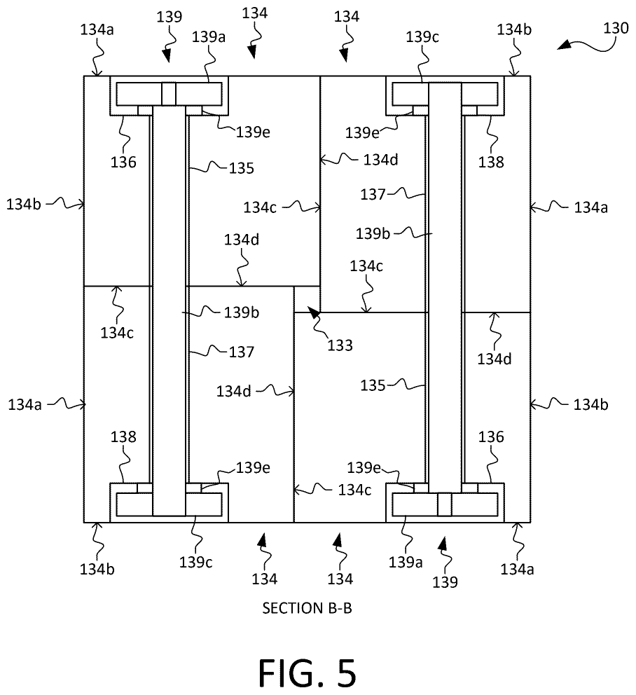

In some embodiments, the plurality of first mounting holes 135 and the plurality of second mounting holes 137 may be arranged off-center on the respective first side 134a and second side 134b of each rectangular member 134, as shown in FIG. 4 and FIG. 5. Accordingly, the forces applied by the plurality of fasteners 139 may be away from the reflective surfaces of the aperture 133 (i.e., portions of the third side 134c of each rectangular member 134), which can minimize the local deflection of the reflective surfaces due to the force from each of the plurality of fasteners 139.

In some embodiments, the plurality of first mounting holes 135 of each rectangular member 134 may comprise a first entrance mounting hole 135a arranged proximal to the beam entrance 131, a first exit mounting hole 135b arranged proximal to the beam exit 132, and a plurality of first intermediate mounting holes 135c arranged between the first entrance mounting hole 135a and the first exit mounting hole 135b. Similarly, the plurality of second mounting holes 137 of each rectangular member 134 may comprise a second entrance mounting hole 137a arranged proximal to the beam entrance 131, a second exit mounting hole 137b arranged proximal to the beam exit 132, and a plurality of second intermediate mounting holes 137c arranged between the second entrance mounting hole 137a and the second exit mounting hole 137b.

Referring to the side view of the tunnel optic 130 shown in FIG. 2, a spacing D1 between the first entrance mounting hole 135a and a nearest one of the plurality of first intermediate mounting holes 135c may be less than a spacing D2 between the plurality of first intermediate mounding holes. Similarly, a spacing D3 between the first exit mounting hole 135b and a nearest one of the plurality of first intermediate mounting holes 135c may be less than the spacing D2 between the plurality of first intermediate mounting holes 135c. The spacing D1 may be equal to the spacing D3. Referring to the top view of the tunnel optic 130 shown in FIG. 3, a spacing D4 between the first entrance mounting hole 135a and a nearest one of the plurality of first intermediate mounting holes 135c may be less than a spacing D5 between the plurality of first intermediate mounding holes. Similarly, a spacing D6 between the first exit mounting hole 135b and a nearest one of the plurality of first intermediate mounting holes 135c may be less than the spacing D5 between the plurality of first intermediate mounting holes 135c. The spacing D4 may be equal to the spacing D6. The spacing D4 and the spacing D6 may be less than the spacing D1 and the spacing D3. The spacing D5 may be less than the spacing D2. The individual dimensions of the spacings may depend on the number of mounting holes provided on each side of the rectangular member 134, the sizes of the mounting holes, and the length of the rectangular member 134. With the plurality of first mounting holes 135 and the plurality of second mounting holes 137 arranged in this manner (i.e., the middle mounting holes evenly spaced and the end mounting holes spaced closer together/closer to the ends of the tunnel optic 130), the flatness of the reflective surfaces of the four rectangular members 134 can be maintained while force is applied by the plurality of fasteners 139 to secure the four rectangular members 134 together. In general, increasing the number of fasteners may increase the overall stiffness and flatness of the tunnel optic 130, which can improve the robustness of the tunnel optic 130. However, the number of fasteners and spacing thereof may depend on the stiffness of the material used for the four rectangular member 134. In some embodiments, the number of fasteners and spacing thereof may be selected such that the compression cones formed by each bolt head of adjacent fasteners overlap when they reach the boundary between the two members being fastened together.

In some embodiments, the plurality of fasteners 139 may be secured within the plurality of first intermediate mounting holes 135c prior to the first entrance mounting hole 135a and the first exit mounting hole 135b. Similarly, the plurality of fasteners 139 may be secured within the plurality of second intermediate mounting holes 137c prior to the second entrance mounting hole 137a and the second exit mounting hole 137b. In other words, the four rectangular members 134 may be secured together by first securing the fasteners in the middle of the tunnel optic 130 and working out toward the ends of the tunnel optic 130. By securing the plurality of fasteners 139 in the plurality of first intermediate mounting holes 135c and/or the plurality of second intermediate mounting holes 137c before securing the plurality of fasteners 139 in the first entrance mounting hole 135a, the first exit mounting hole 135b, the second entrance mounting hole 137a, and the second exit mounting hole 137b, the straightness of each rectangular member 134 can be maintained while reducing the waviness and non-perpendicularity between adjacent reflective surfaces of the tunnel optic 130.

In some embodiments, two of the rectangular members 134 may be secured together first, followed by the third and fourth rectangular members 134. An interferometer can be used to inspect the secured rectangular members 134 to see if unacceptable distortion has been introduced. If the distortion is acceptable, the third rectangular member 134 can be secured to the two rectangular members 134, followed by re-inspection before securing the fourth rectangular member 134.

In some embodiments, the central-to-end tightening procedure may be performed for each third of the final torque. For example, the plurality of fasteners 139 may be secured in the plurality of first intermediate mounting holes 135c and the second intermediate mounting holes 137c by torquing them to ⅓ of the final torque, and then the plurality of fasteners 139 may be secured in the first entrance mounting hole 135a, the first exit mounting hole 135b, the second entrance mounting hole 137a, and the second exit mounting hole 137b by torquing them to ⅓ of the final torque. This procedure may be repeated at ⅔ of the final torque, and then repeated to the final torque, which may improve the straightness of the secured rectangular members 134.

With the system 100, the tunnel optic 130 may provide an assembly having reduced waviness of the reflective surfaces of the aperture 133 and reduce non-perpendicularity between adjacent surfaces, which may improve the homogeneity of the uniform EUV light 112 exiting the beam exit 132 of the tunnel optic 130. In addition, the four rectangular members 134 may be individually adjusted by the plurality of fasteners 139 to fine tune the straightness of the aperture 133 and may provide the ability to disassemble the tunnel optic 130 to remove and replace a defective rectangular member 134 that fails to meet specifications. Furthermore, a tunnel optic 130 that is bolted together and made of metal may be much less prone to damage or misalignment during handling than a homogenizer may of brittle glass or ceramic.

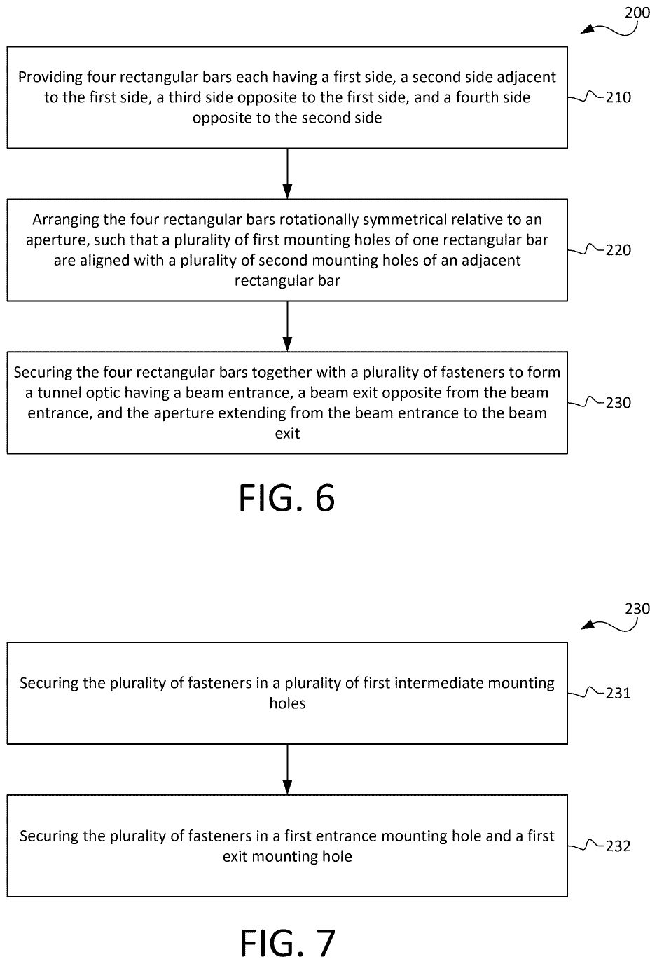

Another embodiment of the present disclosure provides a method 200. As shown in FIG. 6, the method 200 may comprise the following steps.

At step 210, four rectangular members are provided, each having a first side, a second side adjacent to the first side, a third side opposite to the first side, and a fourth side opposite to the second side. A plurality of first mounting holes may be defined in each rectangular member extending from the first side to the third side, and a plurality of second mounting holes may be defined in each rectangular member extending from the second side to the third side. The plurality of first mounting holes may be parallel to the plurality of second mounting holes in each rectangular member.

At step 230, the four rectangular members are secured together with a plurality of fasteners to form a tunnel optic having a beam entrance, a beam exit opposite from the beam entrance, and an aperture extending from the beam entrance to the beam exit. The plurality of first mounting holes of one rectangular member may be aligned with the plurality of second mounting holes of an adjacent rectangular member, such that the plurality of fasteners extend through the plurality of first mounting holes and the plurality of second mounting holes of each rectangular member to secure the four rectangular members together. The aperture of the tunnel optic may be defined by a portion of the third side of each of the four rectangular members.

In some embodiments, before step 230, the method 200 may further comprise step 220. At step 220, the four rectangular members are arranged rotationally symmetrical relative to the aperture, such that the plurality of first mounting holes of one rectangular member are aligned with the plurality of second mounting holes of an adjacent rectangular member.

In some embodiments, the plurality of first mounting holes may comprise a first entrance mounting hole arranged proximal to the beam entrance, a first exit mounting hole arranged proximal to the beam exit, and a plurality of first intermediate mounting holes arranged between the first entrance mounting hole and the first exit mounting hole. Similarly, the plurality of second mounting holes may comprise a second entrance mounting hole arranged proximal to the beam entrance, a second exit mounting hole arranged proximal to the beam exit, and a plurality of second intermediate mounting holes arranged between the second entrance mounting hole and the second exit mounting hole. As shown in FIG. 7, step 230 may comprise the following steps.

At step 231, the plurality of fasteners are secured in the plurality of first intermediate mounting holes. Similarly, the plurality of fasteners may be secured in the plurality of second intermediate mounting holes. The plurality of fasteners may be secured in the plurality of first intermediate mounting holes and/or the plurality of second intermediate mounting holes in an order starting from an innermost mounting hole and working outward to the remaining mounting holes.

At step 232, the plurality of fasteners are secured in the first entrance mounting hole and the first exit mounting hole. Similarly, the plurality of fasteners may be secured in the second entrance mounting hole and the second exit mounting hole. By securing the plurality of fasteners in the plurality of first intermediate mounting holes and/or the plurality of second intermediate mounting holes before securing the plurality of fasteners in the first entrance mounting hole, the first exit mounting hole, the second entrance mounting hole, and the second exit mounting hole, the straightness of each rectangular member can be maintained while reducing the waviness and non-perpendicularity between adjacent reflective surfaces of the tunnel optic.

In some embodiments, two of the rectangular members may be secured together first, followed by the third and fourth rectangular members. In other words, steps 231 and 232 can be repeated three times to secure the four rectangular members together.

In some embodiments, an interferometer can be used to inspect the secured rectangular members 134 to see if unacceptable distortion has been introduced before securing an additional rectangular member to the assembly. If the distortion is acceptable, the third rectangular member can be secured to the two rectangular members, followed by re-inspection before securing the fourth rectangular member.

In some embodiments, the central-to-end tightening procedure of steps 231 and 232 may be performed three times for each pair of rectangular members, each providing a third of the final torque. For example, the plurality of fasteners may be secured in the plurality of first intermediate mounting holes and the second intermediate mounting holes by torquing them to ⅓ of the final torque in step 231, and then the plurality of fasteners may be secured in the first entrance mounting hole, the first exit mounting hole, the second entrance mounting hole, and the second exit mounting hole by torquing them to ⅓ of the final torque in step 232. Steps 231 and 232 may be repeated at ⅔ of the final torque, and then repeated to the final torque, which may improve the straightness of the secured rectangular members.

With the method 200, the assembled tunnel optic may have reduced waviness of the reflective surfaces of the aperture and reduced non-perpendicularity between adjacent surfaces, which may improve the homogeneity of uniform EUV light exiting the beam exit of the tunnel optic. In addition, the four rectangular bars may be individually adjusted by the plurality of fasteners to fine tune the straightness of the aperture and may provide the ability to disassemble the tunnel optic to remove and replace a defective rectangular bar that fails to meet specifications. For example, during the testing within the build process, the tunnel optic may be disassembled into its constituent parts, cleaned, and then reassembled to correct any discovered errors. It can also be disassembled if, at some time in the future, the optical surfaces have become contaminated. The surfaces could be cleaned and then the tunnel optic could be reassembled, which can increase the useful life of the tunnel optic.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a tunnel optic having a beam entrance, a beam exit opposite from the beam entrance, and an aperture extending from the beam entrance to the beam exit;
wherein the tunnel optic comprises four rectangular members secured together by a plurality of fasteners, and each rectangular member has a first side, a second side adjacent to the first side, a third side opposite to the first side, and a fourth side opposite to the second side;
wherein a plurality of first mounting holes are defined in each rectangular member extending from the first side to the third side, and a plurality of second mounting holes are defined in each rectangular member extending from the second side to the third side;
wherein the plurality of first mounting holes are parallel to the plurality of second mounting holes in each rectangular member, and the plurality of first mounting holes of one rectangular member are aligned with the plurality of second mounting holes of an adjacent rectangular member, such that the plurality of fasteners extend through the plurality of first mounting holes and the plurality of second mounting holes of each rectangular member to secure the four rectangular members together; and
wherein the aperture of the tunnel optic is defined by a portion of the third side of each of the four rectangular members.

2. The system of claim 1, wherein the four rectangular members are comprised of nickel-plated aluminum.

3. The system of claim 1, wherein a reflective coating is provided on the third side of each of the four rectangular members defining the aperture.

4. The system of claim 3, wherein the reflective coating is an extreme ultra-violet (EUV) light reflective coating, and the tunnel optic is configured to homogenize EUV light traveling from the beam entrance to the beam exit.

5. The system of claim 1, wherein the plurality of first mounting holes each have a counter bore on the first side defining a first bearing surface, and the plurality of second mounting holes each have a counter bore hole on the second side defining a second bearing surface.

6. The system of claim 5, wherein the plurality of fasteners each comprise a bolt threadably connected to a nut, with a bolt head of the bolt being engaged against the first bearing surface and the nut being engaged against the second bearing surface.

7. The system of claim 6, wherein the plurality of fasteners each further comprise a first spring washer provided between the bolt head and the first bearing surface and a second spring washer provided between the nut and the second bearing surface.

8. The system of claim 1, wherein the plurality of first mounting holes are arranged colinearly on the first side, and the plurality of second mounting holes are arranged colinearly on the second side.

9. The system of claim 8, wherein the plurality of first mounting holes comprise:
a first entrance mounting hole arranged proximal to the beam entrance;
a first exit mounting hole arranged proximal to the beam exit; and
a plurality of first intermediate mounting holes arranged between the first entrance mounting hole and the first exit mounting hole;
wherein a spacing between the first entrance mounting hole and a nearest one of the plurality of first intermediate mounting holes is less than a spacing between the plurality of first intermediate mounting holes, and a spacing between the first exit mounting hole and a nearest one of the plurality of first intermediate mounting holes is less than the spacing between the plurality of first intermediate mounting holes.

10. The system of claim 9, wherein the plurality of fasteners are secured within the plurality of first intermediate mounting holes prior to the first entrance mounting hole and the first exit mounting hole.

11. The system of claim 1, wherein a distance between the first side and the third side is less than a distance between the second side and the fourth side, which defines the portion of the third side of each of the four rectangular members that forms the aperture of the tunnel optic.

12. The system of claim 1, wherein the four rectangular members are arranged rotationally symmetrical relative to the aperture.

13. The system of claim 1, further comprising:
a light source configured to emit EUV light;
a steering mirror configured to direct the EUV light to the beam entrance of the tunnel optic; and
a reticle stage configured to support a reticle pattern illuminated by the EUV light from the beam exit of the tunnel optic.

14. The system of claim 13, further comprising:
an entrance sensor arranged proximal to the beam entrance, wherein the entrance sensor is configured to detect an alignment of the EUV light relative to the aperture of the tunnel optic.

15. The system of claim 14, further comprising:
an exit sensor arranged proximal to the beam exit, wherein the exit sensor is configured to detect an intensity of the EUV light exiting the tunnel optic.

16. The system of claim 15, further comprising:
a carrier configured to support the entrance sensor, the tunnel optic, and the exit sensor; and
an optical stage configured to move the carrier relative to the EUV light to align the EUV light with the aperture of the tunnel optic based on feedback from the entrance sensor.

17. The system of claim 15, wherein the light source is configured to emit pulses of EUV light, and the exit sensor is configured to detect the intensity of each pulse of EUV light exiting the tunnel optic.

18. A method comprising:
providing four rectangular members each having a first side, a second side adjacent to the first side, a third side opposite to the first side, and a fourth side opposite to the second side; and
securing the four rectangular members together with a plurality of fasteners to form a tunnel optic having a beam entrance, a beam exit opposite from the beam entrance, and an aperture extending from the beam entrance to the beam exit;
wherein a plurality of first mounting holes are defined in each rectangular member extending from the first side to the third side, and a plurality of second mounting holes are defined in each rectangular member extending from the second side to the third side;
wherein the plurality of first mounting holes are parallel to the plurality of second mounting holes in each rectangular member, and the plurality of first mounting holes of one rectangular member are aligned with the plurality of second mounting holes of an adjacent rectangular member, such that the plurality of fasteners extend through the plurality of first mounting holes and the plurality of second mounting holes of each rectangular member to secure the four rectangular members together; and
wherein the aperture of the tunnel optic is defined by a portion of the third side of each of the four rectangular members.

19. The method of claim 18, wherein the plurality of first mounting holes comprise:
a first entrance mounting hole arranged proximal to the beam entrance;
a first exit mounting hole arranged proximal to the beam exit; and
a plurality of first intermediate mounting holes arranged between the first entrance mounting hole and the first exit mounting hole;
wherein securing the four rectangular members together with the plurality of fasteners comprises:
securing the plurality of fasteners in the plurality of first intermediate mounting holes; and
securing the plurality of fasteners in the first entrance mounting hole and the first exit mounting hole.

20. The method of claim 19, wherein before securing the four rectangular members together with the plurality of fasteners, the method further comprises:
arranging the four rectangular members rotationally symmetrical relative to the aperture, such that the plurality of first mounting holes of one rectangular member are aligned with the plurality of second mounting holes of an adjacent rectangular member.
